(19) United States
(12) Patent Application Publication
(10) Pub. No.: US 2013/0153031 A1
(43) Pub. Date: Jun. 20, 2013

(54) PHOTOVOLTAIC DEVICE WITH AN ANTI-REFLECTIVE SURFACE AND METHODS OF MANUFACTURING SAME

(71) Applicant: FIRST SOLAR, INC, Perrysburg, OH (US)

(72) Inventors: Yu Yang, Perrysburg, OH (US); Jigish Trivedi, Perrysburg, OH (US)

(73) Assignee: FIRST SOLAR, INC, Perrysburg, OH (US)

(21) Appl. No.: 13/717,789

(22) Filed: Dec. 18, 2012

Related U.S. Application Data
(60) Provisional application No. 61/577,924, filed on Dec. 20, 2011.

(51) Int. Cl. H01L 31/052; H01L 31/18

(52) U.S. Cl. CPC H01L 31/0522; H01L 31/1884
USPC 136/259; 438/72

(57) ABSTRACT

A photovoltaic device comprising a substrate which has a porous first surface and a transparent conductive oxide layer located on a second surface opposite the first surface. A method of manufacturing the device is also described.

### TECHNICAL FIELD

The disclosed embodiments relate generally to a photovoltaic device, and more particularly, to a photovoltaic device with an anti-reflective surface and methods of manufacturing same.

### BACKGROUND

A photovoltaic device can have a substrate, such as a glass sheet, upon which various additional layers can be formed depending on the desired properties of the photovoltaic device. Light can pass through the substrate and be absorbed by semiconductor materials within the photovoltaic device to generate electric power. When the light interacts with the surface of the substrate, a portion of the light can be reflected and therefore will not be utilized to generate electric power.

FIG. 1 shows a cross-sectional view of one example of a photovoltaic (PV) device 1000, which may be a single photovoltaic cell, or a module containing a plurality of photovoltaic cells. The photovoltaic device 1000 can include a barrier layer 1002, a transparent conductive oxide (TCO) layer 1003, a buffer layer 1004, and a semiconductor layer 1010 formed in a stack on substrate 1001. Substrate 1001, which may be glass, can include a surface that is exposed to incident light. The barrier layer 1002, for example silica, alumina or any suitable barrier material, can be formed on the substrate 1001 and functions as a diffusion barrier for preventing chemical elements in substrate 1001 from diffusing into other portions of the device 1000. TCO layer 1003 can be formed on the barrier layer 1002, and acts as a conductor and ohmic contact for carrier transport out of the photovoltaic device. TCO layer 1003 can include any suitable conducting material, such as cadmium stannate, indium tin oxide, or tin oxide. TCO layer 1003 can be annealed to provide improved electrical conductivity. The buffer layer 1004, which may be any buffer layer known in the art, for example, zinc stannate, can be formed on TCO layer 1003 and provides a smooth surface for formation of one or more semiconductor layers.

Each layer may in turn include more than one layer. For example, the semiconductor layer 1010 can include a first layer including a semiconductor window layer 1011, such as a cadmium sulfide layer, formed on the buffer layer 1004 and a second layer including a semiconductor absorber layer 1012, such as a cadmium telluride or copper indium gallium (di)selenide (CIGS) layer, formed adjacent to the semiconductor window layer 1011.

The semiconductor window layer 1011, which is formed adjacent to the semiconductor absorber layer 1012, is usually n-doped while the semiconductor absorber layer 1012 is p-doped. The semiconductor absorber layer 1012 has a high photon absorptivity for generating high current and a suitable band gap to provide a good voltage. Photovoltaic device 1000 can also include a conductive back contact layer 1013 adjacent to semiconductor absorber layer 1012. Multiple photovoltaic cells can be formed on a common substrate 1001 and covered by a back cover 1014 to form a photovoltaic module, as an example of photovoltaic device 1000.

Each layer can cover all or a portion of the device and/or all or a portion of the layer immediately below or substrate underlying the layer. For example, a layer can include any amount of any material that contacts all or a portion of a surface. It should be appreciated that photovoltaic device 1000 can be formed by any suitable process. Further, photovoltaic device 1000 can be manufactured in the layer sequence described above or with a different layer sequence.

The amount of electricity produced by a photovoltaic device, such as the device of FIG. 1, is proportional to the amount of light absorbed by the device. Substrate 1001 is often made out of a material, such as glass, that reflects some incident light. The reflected light cannot be absorbed by the photovoltaic device. If less light was reflected, then the photovoltaic device could generate more electricity.

### DESCRIPTION OF DRAWINGS

FIG. 1 is a diagram illustrating a photovoltaic device.

FIG. 2 is a diagram illustrating a substrate with a porous surface.

FIG. 3 is a diagram illustrating a substrate with anti-reflective coating and a protective layer on top of a TCO layer.

FIG. 4 is a diagram illustrating an anti-reflective surface-creating process

FIG. 5 is a diagram illustrating an anti-reflective surface-creating process.

FIG. 6 is a diagram illustrating an anti-reflective surface-creating process.

FIG. 7 is a diagram illustrating an anti-reflective surface-creating process.

FIG. 8 is a flow chart illustrating a process of making an anti-reflective surface.

FIG. 9 is a flow chart illustrating a process of making an anti-reflective surface.

FIG. 10 is a diagram illustrating a photovoltaic device.

### DETAILED DESCRIPTION

The amount of light reflected by substrate 1001 can be reduced by an anti-reflective coating on the outer surface of substrate 1001. The anti-reflective coating can be a multilayer thin film with alternating high refractive index and low refractive index materials, or a single layer of low refractive index relative to glass (the refractive index of glass is n=1.52). An applied anti-reflective coating can include MgF₂ (magnesium fluoride), fluoro-polymers, or a porous film material.

Anti-reflective coatings are sometimes applied on a substrate using a sol-gel coating process. In such a process solid (nano)particles of a non-reflective material, which collectively are called a precursor, are dispersed in a solution (a sol). The solution is applied onto a surface. There, the (nano)particles agglomerate together to form a continuous three-dimensional network extending throughout the liquid (a gel), which becomes the anti-reflective coating upon being cured. However, using sol-gel technology to apply an anti-reflective coating onto a photovoltaic device 1000 has its challenges.

Creating an anti-reflective coating from a sol-gel process requires performing a heat treatment to anneal the sol-gel coating. If the substrate 1001 was to be annealed after applying the precursor thereon, it would expose TCO layer 1003 to annealing conditions or to annealing time that could damage or alter its properties.

On the other hand, if the anti-reflective coating were to be applied before the TCO layer is formed, the anti-reflective coating might not survive the thermal and/or chemical processes to which the TCO layer or the photovoltaic device 1000 might later be exposed as subsequent materials or layers are added.

According to one disclosed embodiment, an anti-reflective surface is formed on the outer (i.e., sunny side) surface of the substrate. During formation of the anti-reflective surface, the TCO layer 1003, if present, is not substantially degraded or otherwise altered, allowing for normal subsequent processing steps in forming a finished photovoltaic device 1000 to be used. Once formed, the anti-reflective surface can increase the proportion of incoming light being absorbed by the photovoltaic device, thereby increasing the efficiency of the device.

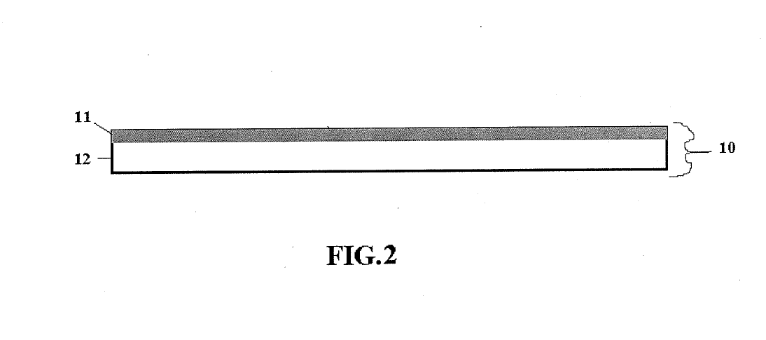

Referring to FIG. 2, a substrate 10, which may be a glass sheet, has a porous, anti-reflective surface 11 formed thereon. The substrate still contains a non-porous portion 12. Note that in FIG. 2 the TCO layer has not yet been formed on substrate 10 and thus there is no need to be concerned about damaging the TCO layer while forming the anti-reflective surface 11.

Anti-reflective surface 11 can be porous with a pore size in the nm- or sub-μm-range (pore size is conventionally defined as the diameter of the largest sphere that may be accommodated within the pore). The porous structure of anti-reflective surface may be skeletonized, wherein the porous structure has walls or columns that provide a rigid scaffold, or skeleton, for the porous structure that allows the pores to retain their size and shape. This porosity can be achieved by etching, among other methods. Anti-reflective surface 11 can have a thickness anywhere between 80-200 nm, with the actual thickness of anti-reflective layer 11 being dependent upon light-transmission efficiency requirements of the photovoltaic device, taking into consideration the precise refractive index of anti-reflective surface 11. For example, as determined by the structure and composition of anti-reflective surface 11, a thickness of 120 nm may be suitable. In some embodiments, the size of pores 15 in the anti-reflective surface 11 may be in the range of 5 to 50 nm.

The porous anti-reflective surface 11 reflects less light than a non-porous surface made of the same material. For example, anti-reflective surface 11 can reflect about 0.5% to about 10%, or about 1% to about 4%, less incident light having a wavelength of about 350 nm to about 1000 nm than the same substrate with a non-porous surface.

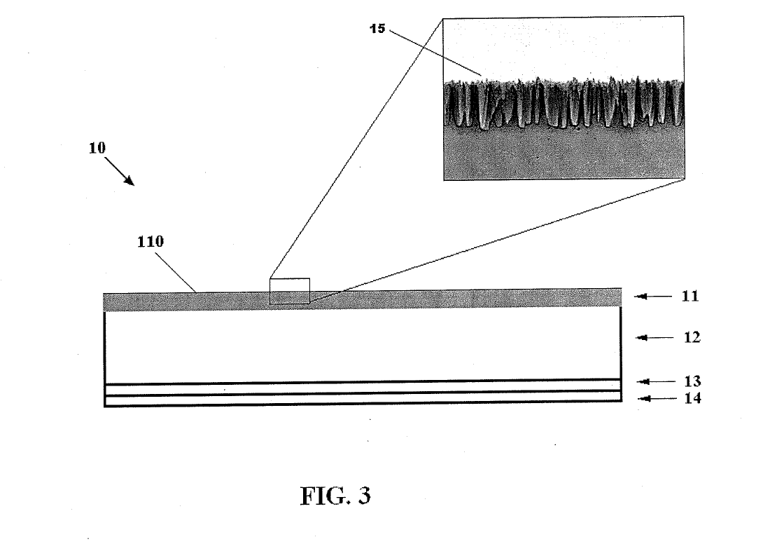

Referring to FIG. 3, substrate 10 includes anti-reflective surface 11 which is formed on a sunny side 110 of substrate 10. TCO layer 13 is on the opposite side from the sunny side. FIG. 3 also shows an enlarged view of anti-reflective surface 11, including the pore structure.

Anti-reflective surface 11 (FIGS. 2 and 3) can acquire its porosity through etching of substrate 10. An etchant can be applied to a sunny side surface of substrate 10, which includes a non-porous portion 12, to form anti-reflective surface 11. If the etchant is an acidic etchant, then basic (alkaline) chemical groups in anti-reflective surface 11 may be neutralized, leaving anti-reflective surface 11 alkaline depleted. When substrate 10 is glass, an alkaline depleted surface can be an additional benefit because glass with an alkaline depleted surface is known to have increased resistance to erosion. The etchant can be applied either before (FIG. 2) or after (FIG. 3) the substrate is coated on the non-sunny side surface with TCO. Etchants suitable for forming a porous, skeletonized anti-reflective surface 11 can be highly corrosive and can damage TCO layer 13 if they come in contact with TCO layer 13. Consequently, to preserve the integrity and functionality of the device, when TCO layer 13 is on the substrate 10, etchants may be prevented from contacting TCO layer 13.

As shown in FIG. 3, TCO layer 13 can be physically protected by forming a protective layer 14 over it. In some embodiments, TCO layer 13 is sufficiently thin such that the amount of etchant that contacts the sides of TCO layer 13 is insubstantial and does not substantially etch TCO layer 13 or otherwise affect the functionality of a fabricated photovoltaic device. In other embodiments, protective layer 14 can cover both the surface and the sides of TCO layer 13.

Protective layer 14 can include an etchant-resistant polymer material, such as polypropylene or polyethylene. When protective layer 14 is formed from such materials, etchants such as aqueous hydrofluoric acid (hydrogen fluoride) or fluorosilicic acid, for example, will not remove protective layer 14. In this embodiment, when an etchant is applied to substrate 10, TCO layer 13 will be protected from degradation or alteration. Protective layer 14, while chemically resistant to the etchant, can be removed, for example by washing it with a solvent that can dissolve it after the etching process has been completed. Such solvents may include organic solvents, such as organic alcohols, ethyl acetate, acetone, methylene chloride, hexanes, diethyl ether, and other solvents known in the art. In some embodiments, protective layer 14 may be omitted if the TCO layer 13 is made of an acid-etchant-resistant oxide such as SnO₂.

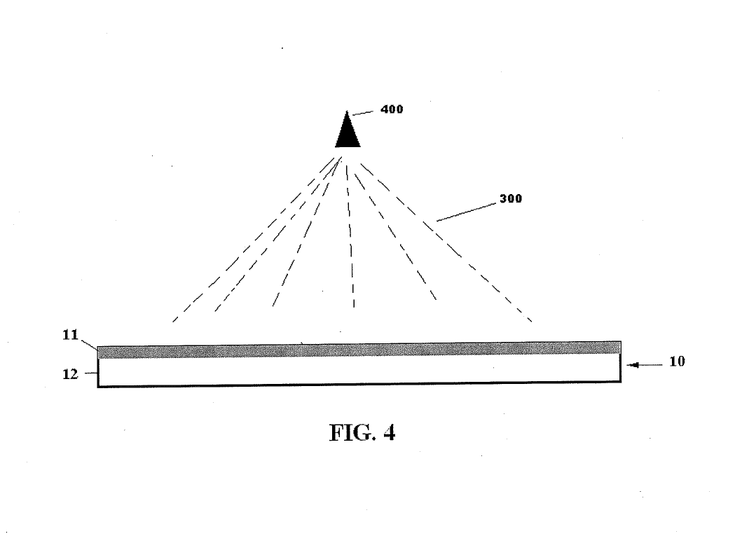

Referring to FIG. 4, etching may occur by spraying the substrate 10 with etchant 300. The surface of substrate 10 that is in contact with etchant 300 becomes the porous, anti-reflective layer 11. The portion that does not contact the etchant 300 remains as a non-porous portion 12. Etchant 300 may be sprayed from a conventional spraying apparatus 400.

Although FIG. 4 illustrates etching of a substrate 10 which does not contain a TCO layer, the technique illustrated in FIG. 4 can also be applied to a substrate containing a TCO layer on its non-sunny side.

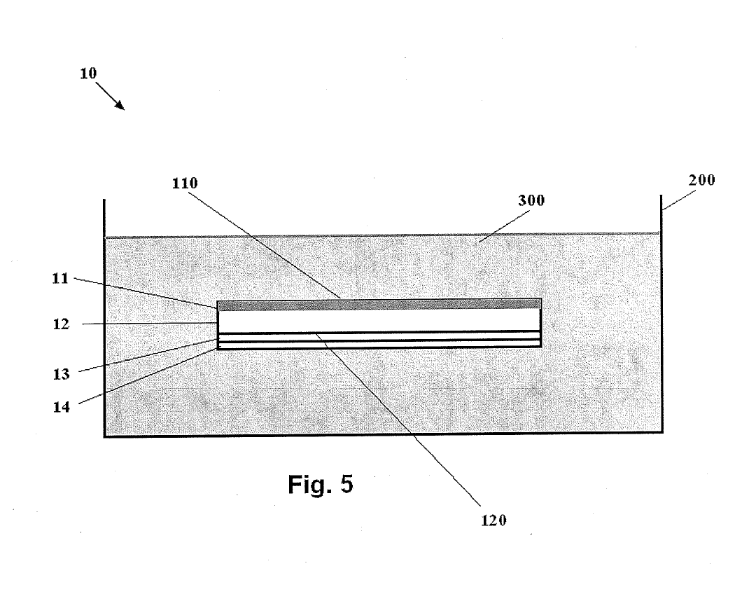

FIG. 5 shows substrate 10 immersed in an etchant 300 within a container 200. Substrate 10 has a sunny side surface 110 and a TCO layer 13 formed adjacent to the non-sunny side surface 120. Prior to etching, a protective layer 14 is formed over TCO layer 13. Protective layer 14 should completely cover the surface of TCO layer 13 while leaving the sunny side surface of substrate 10 exposed. When protective layer 14 is in place, the sunny side of sheet 10 can be exposed to the etchant without disturbing TCO layer 13. As a result, anti-reflective surface 11 can be formed by immersing substrate 10 in container 200 containing etchant 300. Etchant 300 can contact and etch the sunny side of substrate 10. The porous anti-reflective surface 11 includes a skeletonized configuration. After porous anti-reflective surface 11 is formed, substrate 10 still contains a non-porous portion 12. Substrate 10 can be allowed to remain in contact with etchant 300 for any suitable duration to allow etching to occur. A plurality of substrates 10 can be processed in a batch in the same container to allow for fast processing throughput. Substrate 10 can be held in container 200, or can be conveyed through container 200 in an in-process manner.

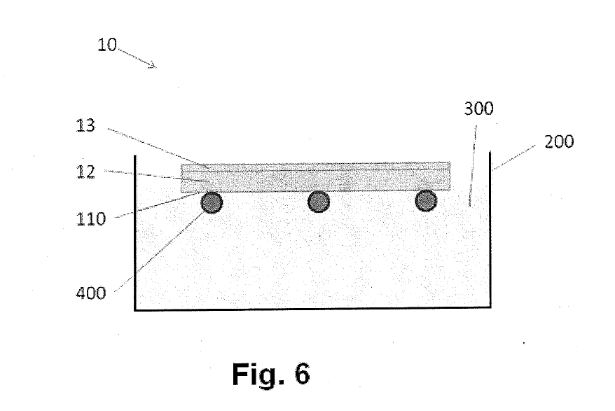

As shown in FIG. 6, substrate 10 can also be conveyed through etchant 300 by any suitable means including a conveyor or rollers 400, such that only a surface portion of the sunny side of substrate 10 is in contact with etchant 300.

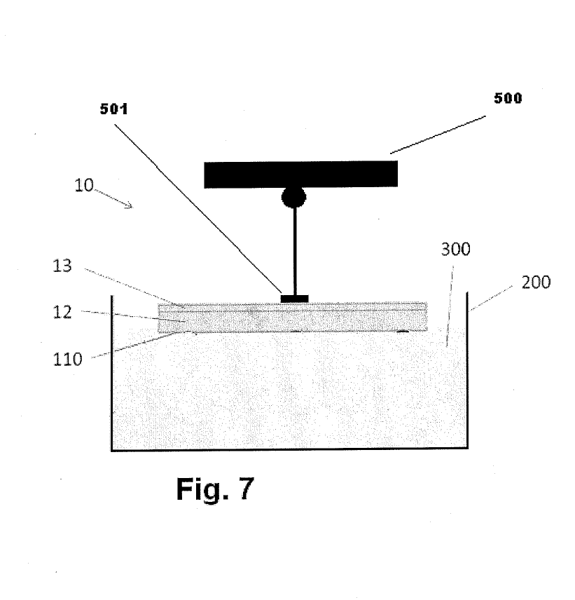

Referring to FIG. 7, substrate 10 can also be suspended from an overhead conveyor 500, which can include one or more substrate 10 securing devices such as one or more suction cups 501, which suspend a sunny side surface of the substrate 10 in the etchant 300. In FIGS. 6 and 7, if the TCO layer 13 is on the back side of the substrate 10, as shown, then protective layer 14 may be omitted since only a portion of the sunny side of substrate 10 is exposed to the etchant. However, it may nonetheless be desirable to protect TCO layer 13 from splashing etchant 300 by using protective layer 14.

Etchant 300 can be selective, only modifying the sunny side surface 110 without affecting TCO layer 13 on the other side, especially when TCO layer 13 is completely covered by protective layer 14. In addition, an etchant 300 can be selected which does not etch the material used for TCO layer 13 (such as when the etchant is hydrogen fluoride and the material used for TCO layer is stannous oxide), in which case protective layer 14 is not needed.

Etchant 300 can include hydrogen fluoride, fluorosilicic acid, or any suitable etching solution. In some embodiments, the etchant 300 can include at least one fluorine-containing compound, such as sodium bifluoride, ammonium bifluoride, or other fluorine-containing etchant which can be used for modifying the glass surface 110. Substrate outer surface 110 can be first treated with one fluorine-containing etchant to remove the glass skin (a thin film covering the glass), and then treated with another fluorine-containing etchant to form an anti-reflective surface 11. For removing the glass skin, the concentration of etchant in solution can be, for example, in the range of 0.5% to 50%. If a hydrogen fluoride etchant is used, then concentration of hydrogen fluoride in solution may be from 0.5% to 5%. If a bifluoride etchant is used, then the concentration of bifluoride in solution may be, for example, from 5% to 25%. For removing the glass skin, an exemplary etching duration, regardless of the etchant, may be in the range between 10 sec and 10 min, preferably 1 to 2 min. For creation of the porous, anti-reflective coating 11 a solution of fluorosilicic acid, hydrofluoric acid, or other fluorine-containing acid can be used as the etchant. When the etchant is used in a solution, the concentration of the etchant in the solution may be 5% to 35%, preferably 10% to 20%. Exemplary etching times for creation of anti-reflective surface 11 are 5 to 90 min, preferably 10 to 45 min.

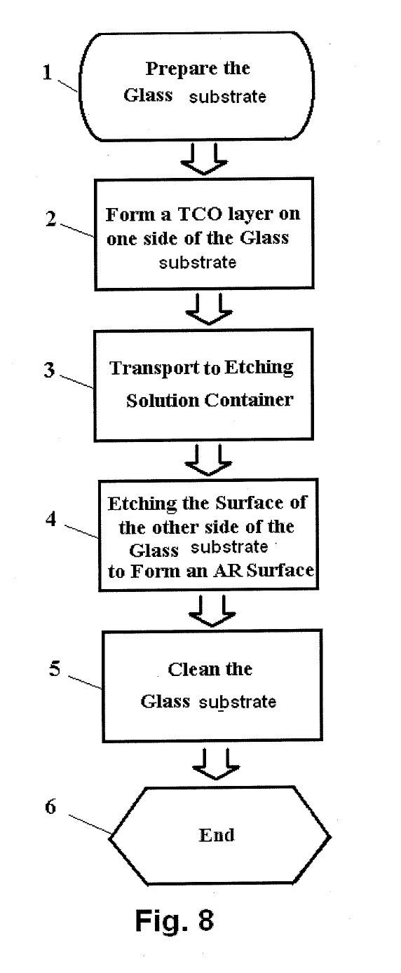

Referring to FIG. 8, a selective anti-reflective surface forming process can include the steps of: (1) preparing the substrate, for example, by forming the substrate to a desired size, and by cleaning the substrate; (2) forming a TCO layer on the non-sunny side of the substrate; (3) transporting the substrate to etchant solution container; (4) etching the surface of the sunny side of the substrate to form an anti-reflective surface; (5) cleaning the substrate to remove etchant and byproducts; and (6) ending the surface process and transporting the glass substrate to the subsequent manufacturing process. The anti-reflective surface forming process can further include forming a protective layer on the TCO layer 13 prior to etching. If a protective layer is used then the protective layer 14 is removed after the process described in steps 4 or 5 of FIG. 8.

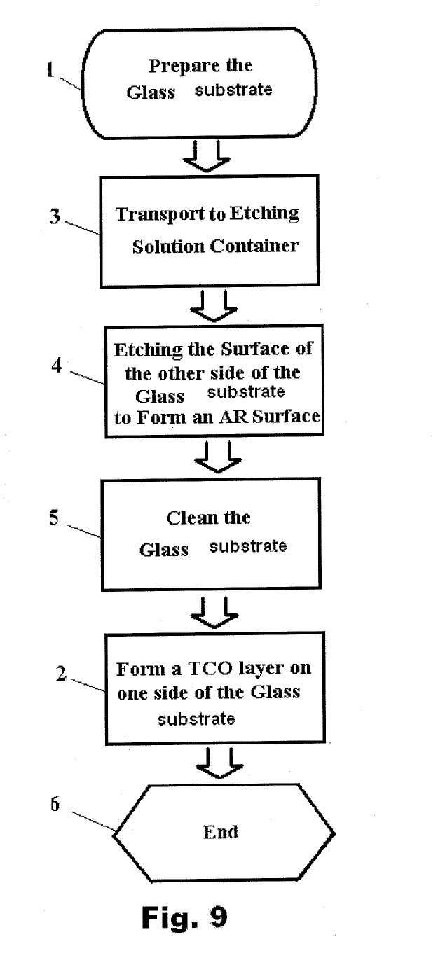

Referring to FIG. 9, in some embodiments step (2) of forming a TCO layer can be done after step (4) etching the surface of the sunny side of the substrate to form an anti-reflective surface and step (5) of cleaning the glass in which case no protective layer is needed for the TCO layer.

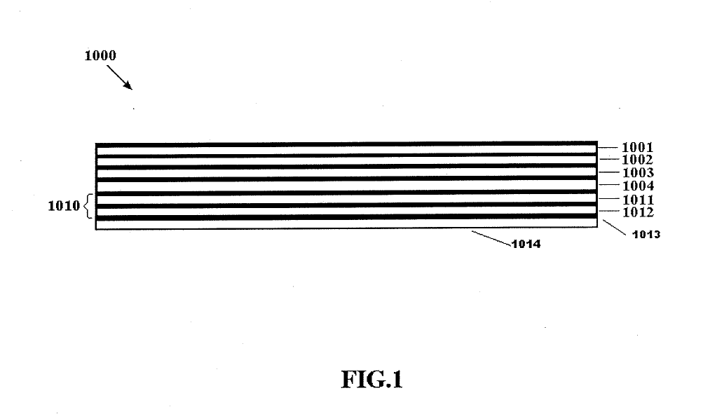

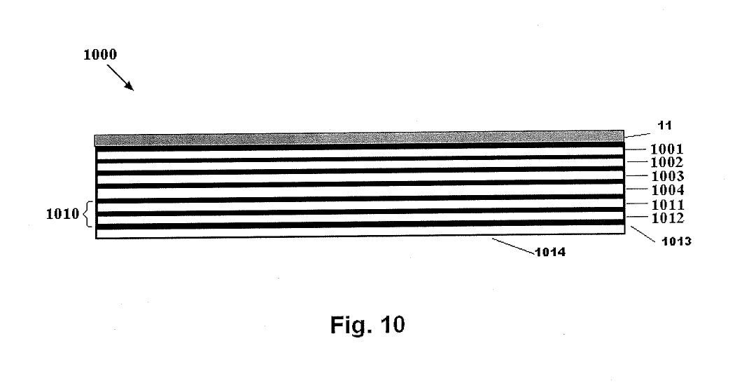

Referring to FIG. 10, a photovoltaic device 1000, for example as shown in FIG. 1, may be formed with an etched anti-reflective surface 11 on the sunny side of substrate 1001. Additional layers may be formed on the non-sunny side of substrate 1001 as described above with reference to FIG. 1.

Although the embodiments above discuss forming the anti-reflective surface by way of an etchant, other means may be used to form the anti-reflective surface. For example, a porous anti-reflective surface may be formed by using a laser, or by using a suitable mechanical means to create pores.

A number of embodiments of the invention have been described. Nevertheless, it will be understood that various modifications may be made without departing from the spirit and scope of the invention. For example, although exemplary photovoltaic devices have been shown and elucidated, the invention can be applied to other devices and technologies. It should also be understood that the appended drawings are not necessarily to scale, presenting a somewhat simplified representation of features illustrative of the basic principles of the invention.

What is claimed is:

1. A photovoltaic device comprising:
a substrate comprising:
a porous first surface as an antireflective surface;
a second surface opposite the first surface; and
a transparent conductive oxide layer on the side of the second surface of the substrate.

2. The photovoltaic device of claim 1, wherein the porous first surface comprises an etched substrate surface.

3. The photovoltaic device of claim 1, wherein the substrate comprises glass.

4. The photovoltaic device of claim 1, wherein the porous first surface is alkaline depleted.

5. The photovoltaic device of claim 1, further comprising a protective layer adjacent to the transparent conductive oxide layer, wherein the protective layer comprises a material that is resistant to etching.

6. The photovoltaic device of claim 5, wherein the protective layer comprises a polymer material.

7. The photovoltaic device of claim 1, wherein the porous first surface reflects about 1% to about 4% less light having a wavelength from about 350 nm to about 1,000 nm, compared to a substrate which has a non-porous surface.

8. The photovoltaic device of claim 1, further comprising a semiconductor material on the side of the second surface of the substrate.

9. The photovoltaic device of claim 8, wherein the semiconductor material comprises a semiconductor window layer and a semiconductor absorber layer adjacent to the semiconductor window layer.

10. The device of claim 9, wherein the semiconductor absorber layer comprises cadmium telluride.

11. The device of claim 9, wherein the semiconductor absorber layer comprises copper indium gallium (di)selenide.

12. The device of claim 9, wherein the semiconductor window layer comprises cadmium selenide.

13. The photovoltaic device of claim 1, wherein the porous first surface comprises a porous skeletonized portion that is positioned adjacent to a substantially non-porous body of the substrate.

14. The photovoltaic device of claim 1, wherein the transparent conductive oxide is resistant to etching.

15. The photovoltaic device of claim 13, wherein the transparent conductive oxide layer comprises tin oxide.

16. An article of manufacture comprising:
a substrate with a first etchable surface and second surface;
a transparent conductive oxide layer adjacent to the second surface; and
an etchant resistant protective layer adjacent to the transparent conductive oxide layer.

17. The article of claim 16, wherein the substrate comprises glass.

18. The article of claim 16, wherein the protective layer comprises a polymer material.

19. The article of claim 18, wherein the polymer material is dissolvable in a solvent.

20. The article of claim 19, wherein the polymer material is selected from the group consisting of polyethylene and polypropylene.

21. A method for manufacturing a photovoltaic module comprising:
providing a light transmitting sheet, the sheet comprising:
a first surface configured to be illuminated, and
a second surface opposite the first surface;
forming a transparent conductive oxide layer adjacent to the second surface; and
contacting the first surface of the sheet with an etchant, thereby making at least a portion of the first surface porous.

22. The method of claim 21, wherein the light transmitting sheet comprises glass.

23. The method of claim 21, wherein the step of contacting the first surface of the light transmitting sheet with an etchant occurs prior to the step of forming a transparent conductive oxide layer.

24. The method of claim 21, wherein the step of forming a transparent conductive oxide layer occurs prior to the step of contacting the light transmitting sheet with an etchant.

25. The method of claim 24, further comprising forming a protective layer covering at least part of the transparent conductive oxide prior to contacting the light transmitting sheet with the etchant.

26. The method of claim 21, wherein the porous first surface portion of the light transmitting sheet reflects about 1% to about 4% less light having a wavelength in the range of about 350 nm to about 1000 nm incident on the porous first surface portion, compared to the light transmitting sheet without a porous surface.

27. The method of claim 21, wherein contacting the first surface of the sheet with the etchant comprises immersing at least part of the light transmitting sheet in a container containing the etchant.

28. The method of claim 27, wherein immersing at least part of the light transmitting sheet in a container containing the etchant comprises conveying the sheet through a container containing the etchant.

29. The method of claim 27 wherein the transparent conductive oxide layer is not immersed in the container containing the etchant.

30. The method of claim 27, wherein the second surface of the sheet is not immersed in the container containing the etchant

31. The method of claim 21, wherein contacting the first surface of the light transmitting sheet with the etchant comprising spraying the light transmitting sheet with an etchant.

32. The method of claim 21, further comprising forming a protective layer adjacent to the transparent conductive oxide layer before contacting the first surface of the light transmitting sheet with the etchant.

33. The method of claim 32, further comprising removing the protective layer after contacting the light transmitting sheet with the etchant.

34. The method of claim 23, wherein the etchant comprises a fluorine-containing compound.

35. The method of claim 34, wherein the etchant comprises hydrogen fluoride.

36. The method of claim 34, wherein the etchant comprises fluorosilicic acid.

37. The method of claim 13, further comprising cleaning the light transmitting sheet after the step of contacting the first surface of the light transmitting sheet with the etchant.
